(19) United States
(12) Patent Application Publication
(10) Pub. No.: US 2015/0021761 A1
(43) Pub. Date: Jan. 22, 2015

(54) MULTI-CHIP PACKAGE

(71) Applicant: Samsung Electronics Co., Ltd., Suwon-si (KR)

(72) Inventor: Chul Park, Hwaseong-si (KR)

(21) Appl. No.: 14/308,958

(22) Filed: Jun. 19, 2014

(30) Foreign Application Priority Data
Jul. 16, 2013 (KR) 10-2013-0083241

(51) Int. Cl. H01L 23/498; H01L 25/065

(52) U.S. Cl. CPC H01L 23/49811; H01L 25/0657
USPC 257/737

(57) ABSTRACT

A multi-chip package may include a package substrate, a plurality of semiconductor chips stacked stepwise on the package substrate, a logic chip and a first conductive wire. The logic chip may include a conductive bump electrically connected to the package substrate. The first conductive wire may be electrically connected between the semiconductor chips and the logic chip.

### CROSS-RELATED APPLICATION

This application claims priority under 35 USC §119 to Korean Patent Application No. 2013-83241, filed on Jul. 16, 2013 in the Korean Intellectual Property Office (KIPO), the contents of which are herein incorporated by reference in their entirety.

### BACKGROUND

1. Field

Exemplary embodiments in accordance with principles of inventive concepts relate to a multi-chip package. More particularly, exemplary embodiments in accordance with principles of inventive concepts relate to a multi-chip package including sequentially stacked semiconductor chips.

2. Description of the Related Art

Generally, various semiconductor fabrication processes may be employed to form a plurality of semiconductor chips on a semiconductor substrate. In order to mount the semiconductor chips on a printed circuit board (PCB), a packaging process may be performed on a semiconductor chip to form a semiconductor package.

In order to increase storage capacity of a semiconductor package, a multi-chip package, including sequentially stacked semiconductor chips, may be used. The multi-chip package may include a package substrate, semiconductor chips sequentially stacked on the package substrate, a logic chip arranged on the package substrate, and conductive wires electrically connected between the semiconductor chips and the package substrate. The logic chip may be electrically connected with the package substrate via conductive bump technology. A bond finger may be formed on the upper surface of the package substrate, outside the logic chip. This, however, increases the width of the multi-chip package.

In order to decrease the width of the multi-chip package, the logic chip may be confined to a lowermost semiconductor chip, with a narrow gap between the lowermost semiconductor chip and the logic chip. However, because a molding member supplied to the gap between the lowermost semiconductor chip and the logic chip may not fill the narrow space between chips, voids may be generated in the molding member.

### SUMMARY

Exemplary embodiments in accordance with principles of inventive concepts provide a multi-chip package that may be capable of preventing a width of the multi-chip package from being increased caused by a logic chip.

According to some exemplary embodiments in accordance with principles of inventive concepts, there may be provided a multi-chip package. The multi-chip package may include a package substrate, a plurality of semiconductor chips, a logic chip and a first conductive wire. The semiconductor chips may be stacked on an upper surface of the package substrate. The logic chip may include a conductive bump electrically connected to the package substrate. The first conductive wire may be electrically connected between the semiconductor chips and the logic chip.

In exemplary embodiments in accordance with principles of inventive concepts, the logic chip may include a redistribution layer connected to the first conductive wire.

In exemplary embodiments in accordance with principles of inventive concepts, the logic chip may further include a connecting wire electrically connected between the redistribution layer and the package substrate.

In exemplary embodiments in accordance with principles of inventive concepts, the connecting wire may be extended in a second horizontal direction substantially perpendicular to a first horizontal direction that may correspond to an extending direction of the first conductive wire.

In exemplary embodiments in accordance with principles of inventive concepts, the logic chip may further include a plug formed in the logic chip. The plug may be electrically connected between the redistribution layer and the conductive bump.

In exemplary embodiments in accordance with principles of inventive concepts, the logic chip may further include a connecting line formed on an outer surface of the logic chip to electrically connect the redistribution layer with the conductive bump.

In exemplary embodiments in accordance with principles of inventive concepts, the multi-chip package may further include a second conductive wire configured to directly connect the semiconductor chips with the package substrate.

In exemplary embodiments in accordance with principles of inventive concepts, the semiconductor chips may be stacked in a stepwise shape.

In exemplary embodiments in accordance with principles of inventive concepts, the semiconductor chips may include a first group of semiconductor chips stacked in the first horizontal direction and directly connected to the package substrate, and a second group of semiconductor chips stacked on the first group of the semiconductor chips in a third horizontal direction substantially opposite to the first horizontal direction. The second group of the semiconductor chips may be electrically connected with the logic chip via the first conductive wire.

In exemplary embodiments in accordance with principles of inventive concepts, the logic chip may be positioned under the second group of the semiconductor chips protruded from the first group of the semiconductor chips in the first horizontal direction.

In exemplary embodiments in accordance with principles of inventive concepts, the multi-chip package may further include a molding member formed on the upper surface of the package substrate to cover the semiconductor chips and the logic chip, and external terminals mounted on a lower surface of the package substrate.

According to some exemplary embodiments in accordance with principles of inventive concepts, there may be provided a multi-chip package. The multi-chip package may include a package substrate, a plurality of semiconductor chips, a logic chip, a dummy chip and a first conductive wire. The semiconductor chips may be stacked on an upper surface of the package substrate. The logic chip may include a conductive bump electrically connected to the package substrate. The dummy chip may be stacked on the logic chip. The dummy chip may be electrically connected with the logic chip via the package substrate. The first conductive wire may be electrically connected between the semiconductor chips and the dummy chip.

In exemplary embodiments in accordance with principles of inventive concepts, the dummy chip may include a redistribution layer connected to the first conductive wire.

In exemplary embodiments in accordance with principles of inventive concepts, the dummy chip may further include a connecting wire electrically connected between the redistribution layer and the package substrate.

In exemplary embodiments in accordance with principles of inventive concepts, the connecting wire may be extended in a second horizontal direction substantially perpendicular to a first horizontal direction that may correspond to an extending direction of the first conductive wire.

According to exemplary embodiments in accordance with principles of inventive concepts, the first conductive wire may electrically connect the semiconductor chips with the package substrate via the logic chip. Thus, it may not be required to form a bond finger, which may be connected to the first conductive wire, on the package substrate. As a result, the logic chip may not act as to increase the width of the multi-chip package. Further, a sufficiently wide space may be formed between the logic chip and a lowermost semiconductor chip so that a sufficient amount of the molding member may be supplied to wide space, thereby preventing generations of voids in the molding member.

### BRIEF DESCRIPTION OF THE DRAWINGS

Exemplary embodiments in accordance with principles of inventive concepts will be more clearly understood from the following detailed description taken in conjunction with the accompanying drawings. FIGS. 1 to 14 represent non-limiting, exemplary embodiments in accordance with principles of inventive concepts as described herein.

FIG. 1 is a cross-sectional view illustrating a multi-chip package in accordance with principles of inventive concepts;

FIG. 2 is a plan view illustrating the multi-chip package substrate in FIG. 1;

FIG. 3 is an enlarged cross-sectional view of a portion “III” in FIG. 1;

FIG. 4 is a cross-sectional view illustrating a multi-chip package in accordance with principles of inventive concepts;

FIG. 5 is a plan view illustrating the multi-chip package substrate in FIG. 4;

FIG. 6 is an enlarged cross-sectional view of a portion “VI” in FIG. 4;

FIG. 7 is a cross-sectional view illustrating a multi-chip package in accordance with principles of inventive concepts;

FIG. 8 is a plan view illustrating the multi-chip package substrate in FIG. 7;

FIG. 9 is an enlarged cross-sectional view of a portion “IX” in FIG. 7;

FIG. 10 is a cross-sectional view illustrating a multi-chip package in accordance with principles of inventive concepts;

FIG. 11 is a cross-sectional view illustrating a multi-chip package in accordance with principles of inventive concepts;

FIG. 12 is a cross-sectional view illustrating a multi-chip package in accordance with principles of inventive concepts;

FIG. 13 is a plan view illustrating the multi-chip package substrate in FIG. 12; and

FIG. 14 is an enlarged cross-sectional view of a portion “XIV” in FIG. 12.

### DETAILED DESCRIPTION OF THE EMBODIMENTS

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example. may be used herein to describe various elements, components, regions, layers and/or sections, these elements, components, regions, layers and/or sections should not be limited by these terms. These terms are only used to distinguish one element, component, region, layer or section from another region, layer or section. In this manner, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. In this manner, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. In this manner, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In this manner, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments in accordance with principles of inventive concepts will be explained in detail with reference to the accompanying drawings.

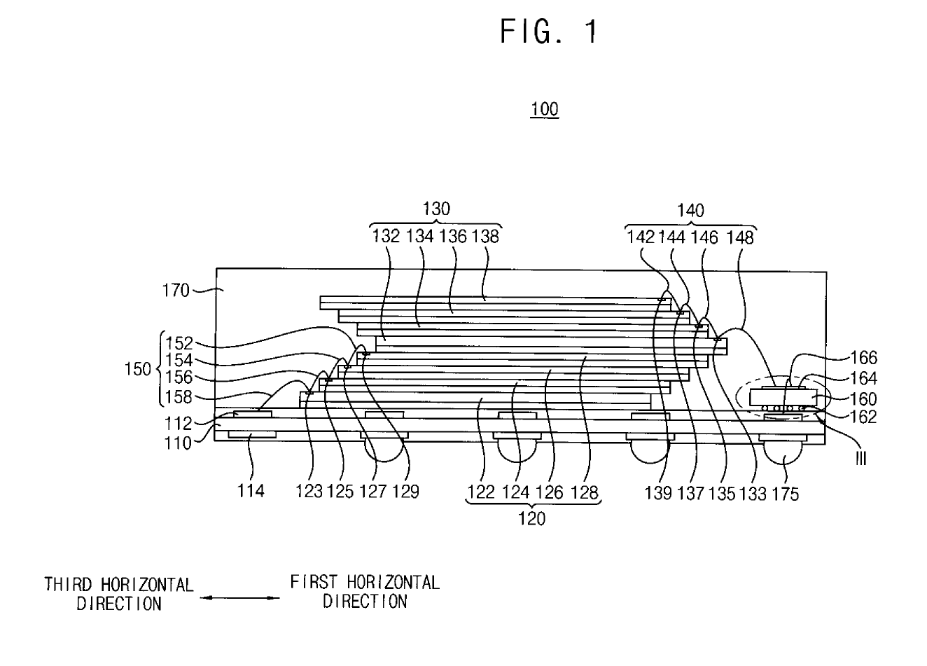

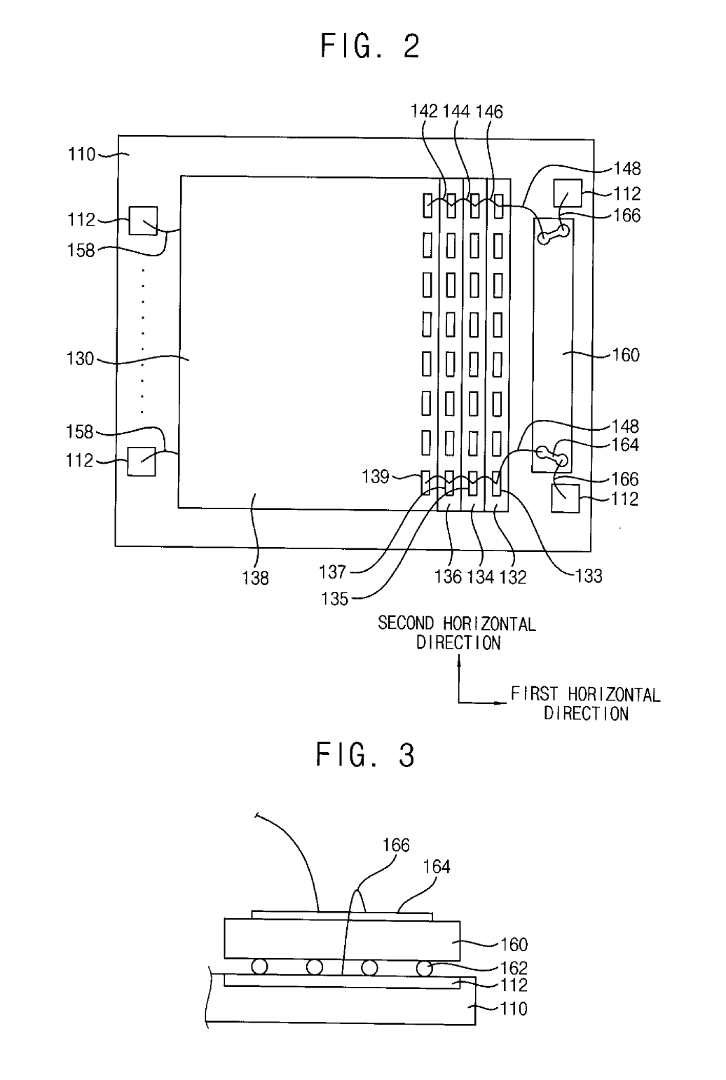

FIG. 1 is a cross-sectional view illustrating an exemplary embodiment of a multi-chip package in accordance with principles of inventive concepts, FIG. 2 is a plan view illustrating the multi-chip package substrate in FIG. 1, and FIG. 3 is an enlarged cross-sectional view of a portion “III” in FIG. 1.

Referring to FIG. 1, a multi-chip package 100 in accordance with principles of inventive concepts may include a package substrate 110, a first group of semiconductor chips 120, a second group of semiconductor chips 130, a logic chip 160, a first conductive wire 140, a second conductive wire 150, a molding member 170 and external terminals 175.

The package substrate 110 may include an insulating substrate, a bond finger 112 and a ball land 114. The bond finger 112 may be arranged on an upper surface of the insulating substrate. The ball land 114 may be arranged on a lower surface of the insulating substrate. The insulating substrate may have a circuit electrically connected between the bond finger 112 and the ball land 114, for example.

A first group of the semiconductor chips 120 may be stacked on the upper surface of the package substrate 110. In exemplary embodiments in accordance with principles of inventive concepts, the first group of the semiconductor chips 120 may include a first semiconductor chip 122, a second semiconductor chip 124, a third semiconductor chip 126 and a fourth semiconductor chip 128. The first semiconductor chip 122 may be placed on the upper surface of the package substrate 110; second semiconductor chip 124 may be placed on an upper surface of the first semiconductor chip 122; third semiconductor chip 126 may be placed on an upper surface of the second semiconductor chip 124; and fourth semiconductor chip 128 may be placed on an upper surface of the third semiconductor chip 126. The first semiconductor chip 122, the second semiconductor chip 124, the third semiconductor chip 126 and the fourth semiconductor chip 128 may have substantially the same size (they may, for example, have the same top- and bottom-surface area or footprint). The first semiconductor chip 122 may have a first bonding pad 123; second semiconductor chip 124 may have a second bonding pad 125; third semiconductor chip 126 may have a third bonding pad 127; and fourth semiconductor chip 128 may have a fourth bonding pad 129. In exemplary embodiments in accordance with principles of inventive concepts, first bonding pad 123 may be positioned on a first edge portion, also referred to herein as a left edge portion of the upper surface of the first semiconductor chip 122; second bonding pad 125 may be positioned on a left edge portion of the upper surface of the second semiconductor chip 124; third bonding pad 127 may be positioned on a left edge portion of the upper surface of the third semiconductor chip 126; and fourth bonding pad 129 may be positioned on a left edge portion of an upper surface of the fourth semiconductor chip 128.

In exemplary embodiments in accordance with principles of inventive concepts, the first semiconductor chip 122, the second semiconductor chip 124, the third semiconductor chip 126 and the fourth semiconductor chip 128 may be stacked in a stepwise fashion. Given such stepwise stacking, a side surface opposite the left edge, also referred to herein as the right side surface of the second semiconductor chip 124 may protrude from a right side surface of the first semiconductor chip 122 in a first horizontal direction; a right side surface of the third semiconductor chip 126 may protrude from the right side surface of the second semiconductor chip 124 in the first horizontal direction; and a right side surface of the fourth semiconductor chip 128 may protrude from the right side surface of the third semiconductor chip 126 in the first horizontal direction. As a result, the first bonding pad 123, the second bonding pad 125, the third bonding pad 127 and the fourth bonding pad 129, which may be arranged on the left edge portions of the first semiconductor chip 122, the second semiconductor chip 124, the third semiconductor chip 126 and the fourth semiconductor chip 128, may be upwardly exposed.

The second group of semiconductor chips 130 may be stacked on the upper surface of the first group of the semiconductor chips 120. In exemplary embodiments in accordance with principles of inventive concepts, the second group of the semiconductor chips 130 may include a fifth semiconductor chip 132, a sixth semiconductor chip 134, a seventh semiconductor chip 136 and an eighth semiconductor chip 138. The fifth semiconductor chip 132 may be placed on the upper surface of the fourth semiconductor chip 128; sixth semiconductor chip 134 may be placed on an upper surface of the fifth semiconductor chip 132; seventh semiconductor chip 136 may be placed on an upper surface of the sixth semiconductor chip 134; and eighth semiconductor chip 138 may be placed on an upper surface of the seventh semiconductor chip 136. The fifth semiconductor chip 132, the sixth semiconductor chip 134, the seventh semiconductor chip 136 and the eighth semiconductor chip 138 may have substantially the same size (they may, for example, have the same top- and bottom-surface area or footprint). Additionally, the size of the fifth semiconductor chip 132, the sixth semiconductor chip 134, the seventh semiconductor chip 136 and the eighth semiconductor chip 138 may be substantially the same as that of the first semiconductor chip 122, the second semiconductor chip 124, the third semiconductor chip 126 and the fourth semiconductor chip 128. The fifth semiconductor chip 132 may have a fifth bonding pad 133; sixth semiconductor chip 134 may have a sixth bonding pad 135; seventh semiconductor chip 136 may have a seventh bonding pad 137; and eighth semiconductor chip 138 may have an eighth bonding pad 139. In exemplary embodiments in accordance with principles of inventive concepts, fifth bonding pad 133 may be positioned on a second edge portion opposite the first edge portion, also referred to herein as a right edge portion of the upper surface of the fifth semiconductor chip 132; sixth bonding pad 135 may be positioned on a right edge portion of the upper surface of the sixth semiconductor chip 134; seventh bonding pad 137 may be positioned on a right edge portion of the upper surface of the seventh semiconductor chip 136; and eighth bonding pad 139 may be positioned on a right edge portion of an upper surface of the eighth semiconductor chip 138.

In exemplary embodiments in accordance with principles of inventive concepts, the fifth semiconductor chip 132, the sixth semiconductor chip 134, the seventh semiconductor chip 136 and the eighth semiconductor chip 138 may be stacked in a stepwise fashion. Additionally, the fifth semiconductor chip 132, the sixth semiconductor chip 134, the seventh semiconductor chip 136 and the eighth semiconductor chip 138 may be stacked in a third horizontal direction substantially opposite to the first horizontal direction. In exemplary embodiments in accordance with principles of inventive concepts, as illustrated in FIG. 1, the “third horizontal direction” may coincide with the direction of the left edge portion, or first edge portion and the “first horizontal direction may coincide with the direction of the right edge portion, or second portion of semiconductor chips. As a result, a left side surface of the sixth semiconductor chip 134 may protrude from a left side surface of the fifth semiconductor chip 132 in the third horizontal direction; a left side surface of the seventh semiconductor chip 136 may protrude from the left side surface of the sixth semiconductor chip 134 in the third horizontal direction; and a left side surface of the eighth semiconductor chip 138 may protrude from the left side surface of the seventh semiconductor chip 136 in the third horizontal direction. Consequently, the fifth bonding pad 133, the sixth bonding pad 135, the seventh bonding pad 137 and the eighth bonding pad 139, which may be arranged on the right edge portions of the fifth semiconductor chip 132, the sixth semiconductor chip 134, the seventh semiconductor chip 136 and the eighth semiconductor chip 138, may be upwardly exposed.

In exemplary embodiments in accordance with principles of inventive concepts, logic chip 160 may be positioned on a right portion of the upper surface of the package substrate 110, to the side, the right side, for example, of the stacked chips and may include a control, functional block, or chip, for improving operational capacities of the multi-chip package 100. Referring to FIGS. 2 and 3, the logic chip 160 may include a conductive bump 162, a redistribution layer 164 and a connecting wire 166.

The conductive bump 162 may be arranged on a lower surface of the logic chip 160. The conductive bump 162 may be mounted on the bond finger 112 of the package substrate 110. In exemplary embodiments in accordance with principles of inventive concepts, logic chip 160 may be a flip chip. The logic chip 160 may have an active face corresponding to the lower surface of the logic chip 160, for example.

The redistribution layer 164 may be arranged on an upper surface of the logic chip 160. The upper surface of the logic chip 160 may be a non-active face devoid of conductive lines. With the upper surface of logic chip 160 inactive, designs of the redistribution layer 164 on the upper surface of the logic chip 160 may not be restricted.

The connecting wire 166 may be electrically connected between the redistribution layer 164 and the bond finger 112 of the package substrate 110. In exemplary embodiments in accordance with principles of inventive concepts, the connecting wire 166 may be extended in a second horizontal direction substantially perpendicular to the first horizontal direction. With the connecting wire 166 extending in this direction it will not increase the width of the multi-chip package 100.

The first conductive wire 140 may electrically connect the second group of the semiconductor chip 130 with the logic chip 160. Because the logic chip 160 may be electrically connected with the package substrate 110 via the conductive bump 162, the first conductive wire 140 may indirectly connect the second group of the semiconductor chips 130 with the package substrate 110 via the logic chip 160. In exemplary embodiments in accordance with principles of inventive concepts, the first conductive wire 140 may be extended in the first horizontal direction.

In exemplary embodiments in accordance with principles of inventive concepts, the first conductive wire 140 may include a 1-1 conductive wire 142, a 1-2 conductive wire 144, a 1-3 conductive wire 146 and a 1-4 conductive wire 148. The 1-1 conductive wire 142 may be electrically connected between the eighth bonding pad 139 of the eighth semiconductor chip 138 and the seventh bonding pad 137 of the seventh semiconductor chip 136; the 1-2 conductive wire 144 may be electrically connected between the seventh bonding pad 137 of the seventh semiconductor chip 136 and the sixth bonding pad 135 of the sixth semiconductor chip 134; the 1-3 conductive wire 146 may be electrically connected between the sixth bonding pad 135 of the sixth semiconductor chip 134 and the fifth bonding pad 133 of the fifth semiconductor chip 132; and the 1-4 conductive wire 148 may be electrically connected between the fifth bonding pad 133 of the fifth semiconductor chip 132 and the redistribution layer 164 of the logic chip 160.

In such an exemplary embodiment in accordance with principles of inventive concepts, the second group of the semiconductor chip 130 may be electrically connected with the package substrate 110 via the first conductive wire 140, the redistribution layer 164 and the connecting wire 166 and the first conductive wire 140 may not protrude from a right side surface of the logic chip 160 in the first horizontal direction. Because the first conductive wire 140 does not protrude from the right side surface of the logic chip 160 in the first horizontal direction, the multi-chip package 100 may be relatively narrow. Additionally, in accordance with principles of inventive concepts, the connecting wire 166 may be extended in the third horizontal direction substantially perpendicular to the first horizontal direction so that the connecting wire 166 does not protrude from the right side surface of the logic chip 160 and, as a result, the connecting wire 166 does not increase the width of the multi-chip package 100.

Alternatively, in accordance with principles of inventive concepts, the 1-4 conductive wire 148 may be connected to any one of the sixth bonding pad 135, the seventh bonding pad 137 and the eighth bonding pad 139, for example.

The second conductive wire 150 may directly connect the first group of the semiconductor chip 120 with the package substrate 110. In exemplary embodiments in accordance with principles of inventive concepts, the second conductive wire 150 may be extended in the third horizontal direction.

In exemplary embodiments in accordance with principles of inventive concepts, the second conductive wire 150 may include a 2-1 conductive wire 152, a 2-2 conductive wire 154, a 2-3 conductive wire 156 and a 2-4 conductive wire 158. The 2-1 conductive wire 152 may be electrically connected between the fourth bonding pad 129 of the fourth semiconductor chip 128 and the third bonding pad 127 of the third semiconductor chip 126; the 2-2 conductive wire 154 may be electrically connected between the third bonding pad 127 of the third semiconductor chip 126 and the second bonding pad 125 of the second semiconductor chip 124; the 2-3 conductive wire 156 may be electrically connected between the second bonding pad 125 of the second semiconductor chip 124 and the first bonding pad 123 of the first semiconductor chip 122; and the 2-4 conductive wire 158 may be electrically connected between the first bonding pad 123 of the first semiconductor chip 122 and the bond finger 112 of the package substrate 110. Alternatively, in accordance with principles of inventive concepts, the 2-4 conductive wire 158 may be connected to any one of the second bonding pad 125, the third bonding pad 127 and the fourth bonding pad 129, for example.

The molding member 170 may be formed on the upper surface of the package substrate 110 to cover the first group of the semiconductor chips 120, the second group of the semiconductor chip 130 and the logic chip 160. The molding member 170 may protect the first group of the semiconductor chips 120, the second group of the semiconductor chips 130, the first conductive wire 140, the second conductive wire 150 and the logic chip 160 from external environments. In exemplary embodiments in accordance with principles of inventive concepts, the molding member 170 may include an epoxy molding compound (EMC), for example.

In exemplary embodiments in accordance with principles of inventive concepts, because the first conductive wire 140 may be connected to the logic chip 160, logic chip 160 may be located far enough away from the first group of semiconductor chips 120 to allow a sufficient amount of molding member 170 to be introduced to avoid the introduction of voids in molding member 170.

The external terminals 175 may be mounted on the ball land 114 of the package substrate 110. In exemplary embodiments in accordance with principles of inventive concepts, the external terminals 175 may include solder balls.

In exemplary embodiments in accordance with principles of inventive concepts, each of the first group of the semiconductor chips 120 and the second group of the semiconductor chips 130 may include four semiconductor chips. In accordance with principles of inventive concepts each group of semiconductor chips includes a plurality of chips, which may be more or less in number than four semiconductor chips. Additionally, in accordance with principles of inventive concepts, semiconductor chips may be stacked stepwise in at least one direction.

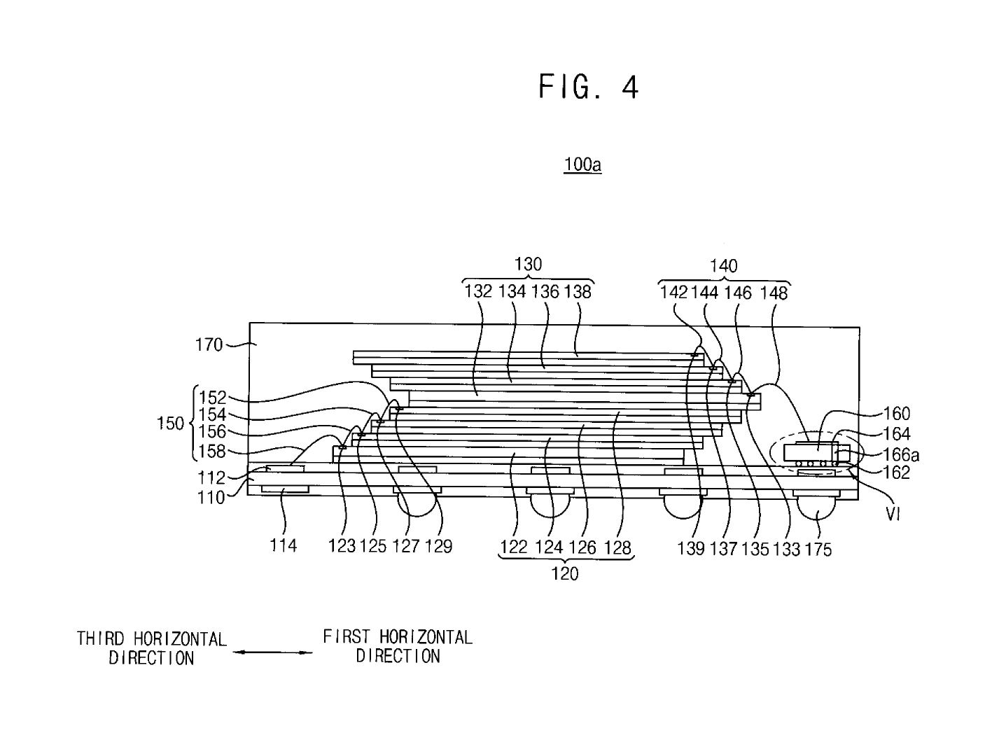

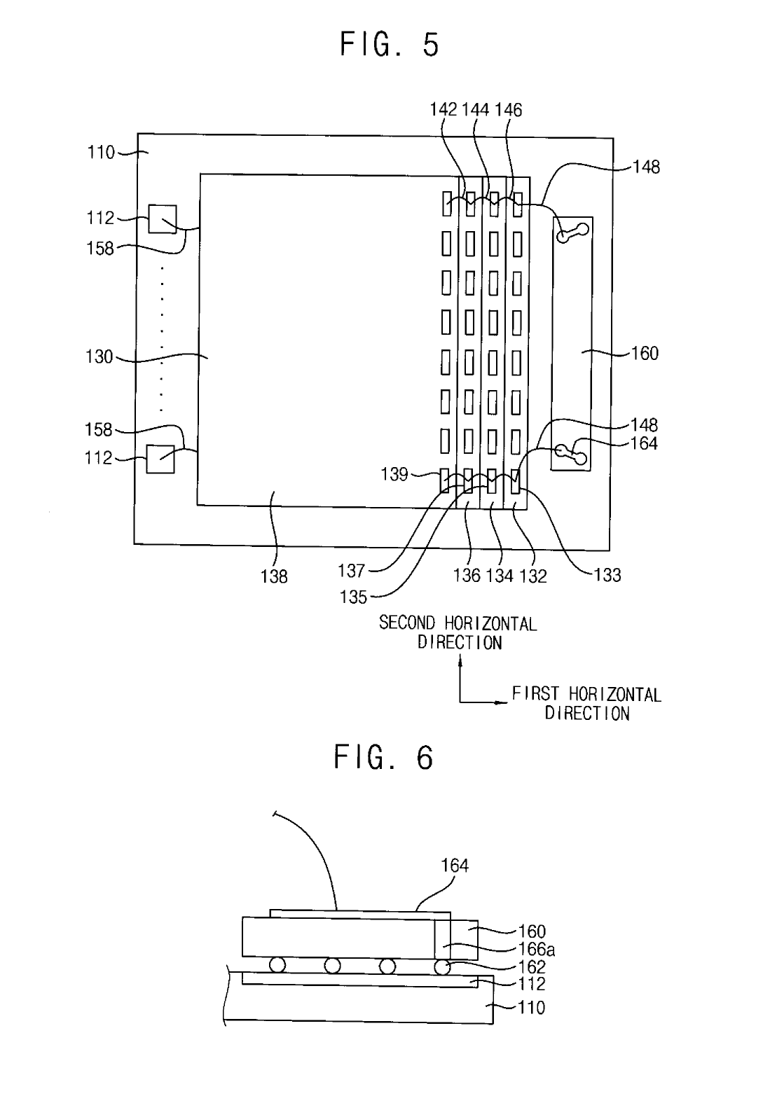

FIG. 4 is a cross-sectional view illustrating an exemplary embodiment of a multi-chip package in accordance with principles of inventive concepts, FIG. 5 is a plan view illustrating the multi-chip package substrate in FIG. 4, and FIG. 6 is an enlarged cross-sectional view of a portion “VI” in FIG. 4.

An exemplary embodiment of a multi-chip package 100a in accordance with principles of inventive concepts includes elements substantially the same as those of the multi-chip package 100 in FIG. 1 except for a logic chip. For the sake of brevity and clarity of description, the same reference numerals may refer to the same elements and any further illustrations with respect to the same elements may not be repeated here.

Referring to FIGS. 4 to 6, a logic chip 160 may include a conductive bump 162, a redistribution layer 164 and a plug 166a. The plug 166a may be vertically formed in the logic chip 160a. The plug 166a may be electrically connected between the redistribution layer 164 and the conductive bump 162.

In this manner, the second group of the semiconductor chips 130 may be electrically connected with the package substrate 110 via the first conductive wire 140, the redistribution layer 164, the plug 166a and the conductive bump 162.

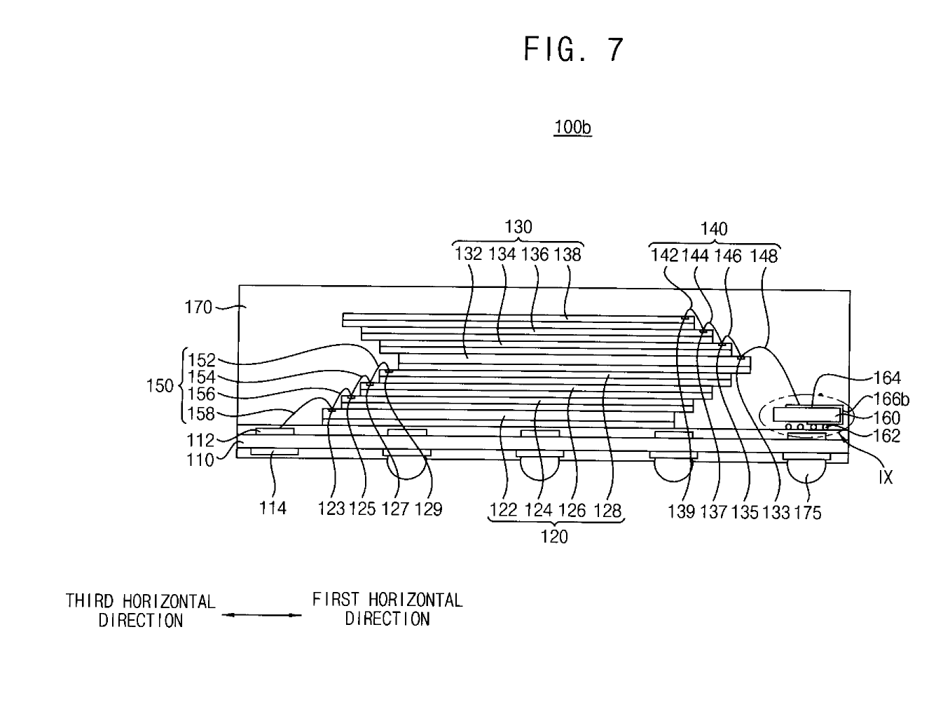

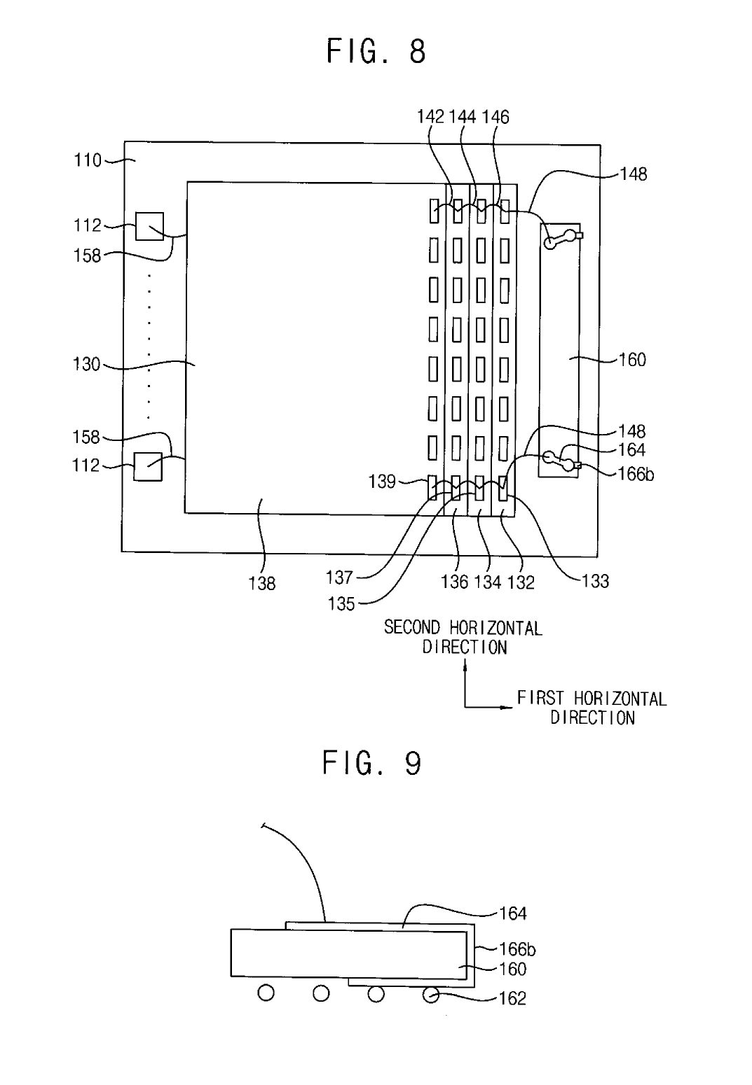

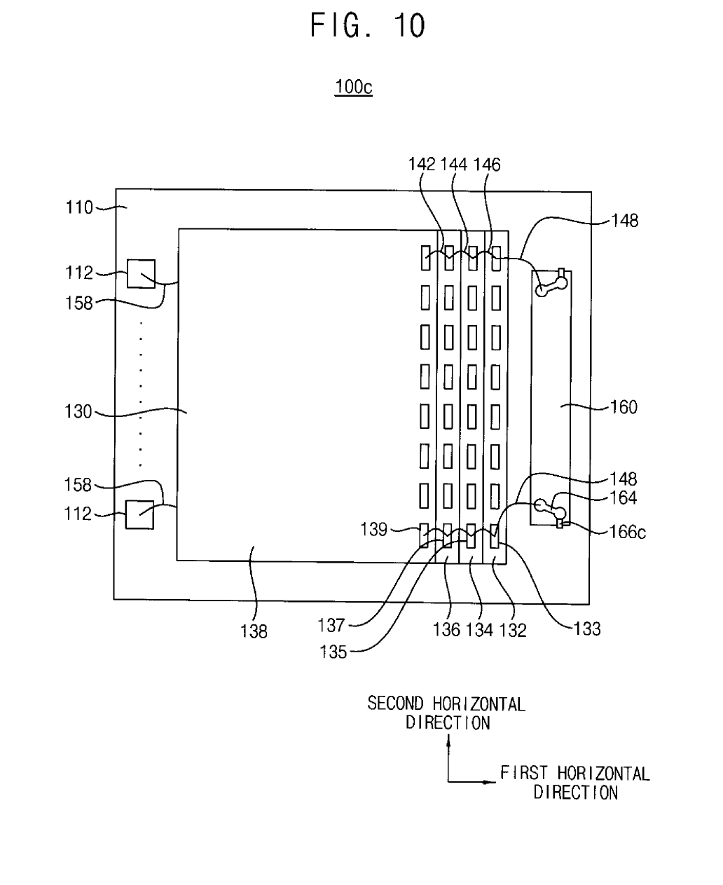

FIG. 7 is a cross-sectional view illustrating an exemplary embodiment of a multi-chip package in accordance with principles of inventive concepts, FIG. 8 is a plan view illustrating the multi-chip package substrate in FIG. 7, and FIG. 9 is an enlarged cross-sectional view of a portion “IX” in FIG. 7.

An exemplary embodiment of a multi-chip package 100b in accordance with principles of inventive concepts may include elements substantially the same as those of the multi-chip package 100 in FIG. 1 except for a logic chip. For the sake of brevity and clarity of explanation descriptions of like elements may not be repeated here.

Referring to FIGS. 7 to 9, a logic chip 160 may include a conductive bump 162, a redistribution layer 164 and a connecting line 166b. The connecting line 166b may be formed on the upper surface, a first side surface oriented in the first horizontal direction, and the lower surface of the logic chip 160. The connecting line 166b may be electrically connected between the redistribution layer 164 and the conductive bump 162.

In this manner, the second group of the semiconductor chips 130 may be electrically connected with the package substrate 110 via the first conductive wire 140, the redistribution layer 164, the connecting line 166b and the conductive bump 162.

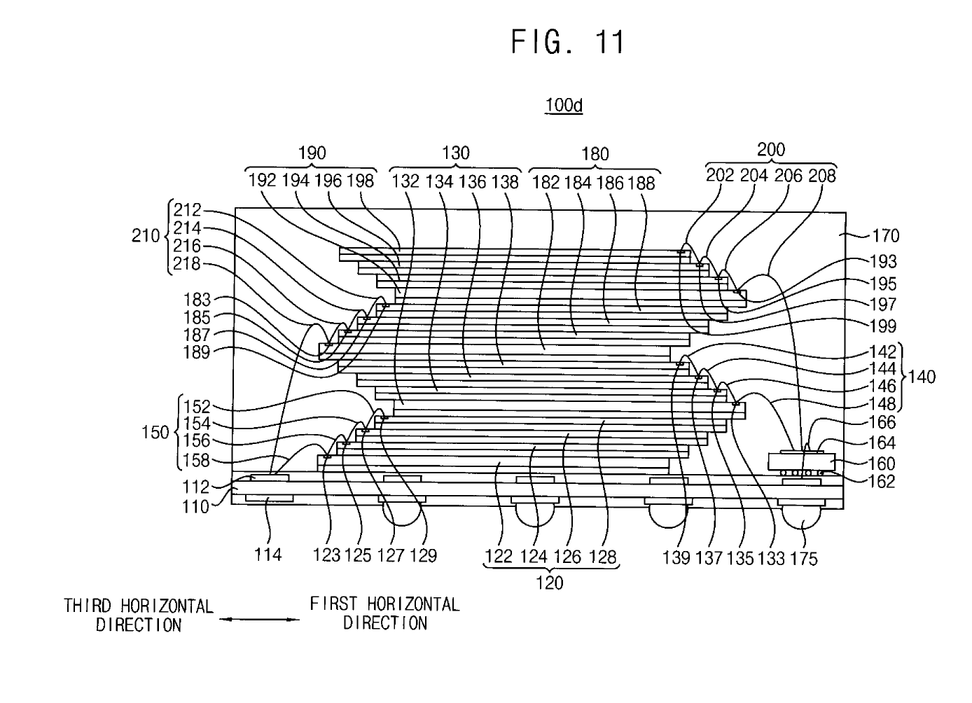

FIG. 10 is a cross-sectional view illustrating a multi-chip package in accordance with exemplary embodiments in accordance with principles of inventive concepts.

An exemplary embodiment of a multi-chip package 100c in accordance with principles of inventive concepts may include elements substantially the same as those of the multi-chip package 100b in FIG. 7 except for a logic chip. For the sake of brevity and clarity of explanation descriptions of like elements may not be repeated here.

Referring to FIG. 10, a connecting line 166c may be formed on the upper surface, a second side surface oriented in the second horizontal direction, and the lower surface of the logic chip 160. The connecting line 166c may be electrically connected between the redistribution layer 164 and the conductive bump 162.

In this manner, the second group of the semiconductor chips 130 may be electrically connected with the package substrate 110 via the first conductive wire 140, the redistribution layer 164, the connecting line 166c and the conductive bump 162.

FIG. 11 is a cross-sectional view illustrating a multi-chip package in accordance with exemplary embodiments in accordance with principles of inventive concepts.

An exemplary embodiment of a multi-chip package 100d in accordance with principles of inventive concepts may include elements substantially the same as those of the multi-chip package 100 in FIG. 1 except for further including a third group of semiconductor chips and a fourth group of semiconductor chips. For the sake of brevity and clarity of explanation descriptions of like elements may not be repeated here.

Referring to FIG. 11, the multi-chip package 100d of this example embodiment may include a third group of semiconductor chips 180 and a fourth group of semiconductor chips 190.

The third group of the semiconductor chips 180 may be stacked on the upper surface of the second group of the semiconductor chips 130. In exemplary embodiments in accordance with principles of inventive concepts, the third group of the semiconductor chips 180 may include a ninth semiconductor chip 182, a tenth semiconductor chip 184, an eleventh semiconductor chip 186 and a twelfth semiconductor chip 188. The ninth semiconductor chip 182 may be placed on the upper surface of the eighth semiconductor chip 138; tenth semiconductor chip 184 may be placed on an upper surface of the ninth semiconductor chip 182; eleventh semiconductor chip 186 may be placed on an upper surface of the tenth semiconductor chip 184; and twelfth semiconductor chip 188 may be placed on an upper surface of the eleventh semiconductor chip 186. The ninth semiconductor chip 182, the tenth semiconductor chip 184, the eleventh semiconductor chip 186 and the twelfth semiconductor chip 188 may have substantially the same size (they may, for example, have the same top- and bottom-surface area or footprint). Further, the size of the ninth semiconductor chip 182, the tenth semiconductor chip 184, the eleventh semiconductor chip 186 and the twelfth semiconductor chip 188 may be substantially the same as that of the first semiconductor chip 122, the second semiconductor chip 124, the third semiconductor chip 126 and the fourth semiconductor chip 128. The ninth semiconductor chip 182 may have a ninth bonding pad 183; tenth semiconductor chip 184 may have a tenth bonding pad 185; eleventh semiconductor chip 186 may have an eleventh bonding pad 187; and twelfth semiconductor chip 188 may have a twelfth bonding pad 189. The ninth bonding pad 183 may be positioned on a left edge portion of the upper surface of the ninth semiconductor chip 182; tenth bonding pad 185 may be positioned on a left edge portion of the upper surface of the tenth semiconductor chip 184; eleventh bonding pad 187 may be positioned on a left edge portion of the upper surface of the eleventh semiconductor chip 186; and twelfth bonding pad 189 may be positioned on a left edge portion of an upper surface of the twelfth semiconductor chip 188.

In exemplary embodiments in accordance with principles of inventive concepts, the ninth semiconductor chip 182, the tenth semiconductor chip 184, the eleventh semiconductor chip 186 and the twelfth semiconductor chip 188 may be stacked in a stepwise fashion. As a result, the ninth bonding pad 183, the tenth bonding pad 185, the eleventh bonding pad 187 and the twelfth bonding pad 189, which may be arranged on the left edge portions of the ninth semiconductor chip 182, the tenth semiconductor chip 184, the eleventh semiconductor chip 186 and the twelfth semiconductor chip 188, may be upwardly exposed.

The fourth group of the semiconductor chips 190 may be stacked on the upper surface of the third group of the semiconductor chips 180. In exemplary embodiments in accordance with principles of inventive concepts, the fourth group of the semiconductor chips 190 may include a thirteenth semiconductor chip 192, a fourteenth semiconductor chip 194, a fifteenth semiconductor chip 196 and a sixteenth semiconductor chip 198. The thirteenth semiconductor chip 192 may be placed on the upper surface of the twelfth semiconductor chip 188; fourteenth semiconductor chip 184 may be placed on an upper surface of the thirteenth semiconductor chip 192; fifteenth semiconductor chip 196 may be placed on an upper surface of the fourteenth semiconductor chip 194; and sixteenth semiconductor chip 198 may be placed on an upper surface of the fifteenth semiconductor chip 196. The thirteenth semiconductor chip 192, the fourteenth semiconductor chip 194, the fifteenth semiconductor chip 196 and the sixteenth semiconductor chip 198 may have substantially the same size (they may, for example, have the same top- and bottom-surface area or footprint). Additionally, the size of the thirteenth semiconductor chip 192, the fourteenth semiconductor chip 194, the fifteenth semiconductor chip 196 and the sixteenth semiconductor chip 198 may be substantially the same as that of the first semiconductor chip 122, the second semiconductor chip 124, the third semiconductor chip 126 and the fourth semiconductor chip 128.

The thirteenth semiconductor chip 192 may have a thirteenth bonding pad 193; fourteenth semiconductor chip 194 may have a fourteenth bonding pad 195; fifteenth semiconductor chip 196 may have a fifteenth bonding pad 197; and sixteenth semiconductor chip 198 may have a sixteenth bonding pad 199. The thirteenth bonding pad 193 may be positioned on a right edge portion of the upper surface of the thirteenth semiconductor chip 192; fourteenth bonding pad 195 may be positioned on a right edge portion of the upper surface of the fourteenth semiconductor chip 194; fifteenth bonding pad 197 may be positioned on a right edge portion of the upper surface of the fifteenth semiconductor chip 196; and sixteenth bonding pad 199 may be positioned on a right edge portion of an upper surface of the sixteenth semiconductor chip 198.

In exemplary embodiments in accordance with principles of inventive concepts, the thirteenth semiconductor chip 192, the fourteenth semiconductor chip 194, the fifteenth semiconductor chip 196 and the sixteenth semiconductor chip 198 may be stacked in a stepwise shape along the third horizontal direction. As a result, the thirteenth bonding pad 193, the fourteenth bonding pad 195, the fifteenth bonding pad 197 and the sixteenth bonding pad 199, which may be arranged on the right edge portions of the thirteenth semiconductor chip 192, the fourteenth semiconductor chip 194, the fifteenth semiconductor chip 196 and the sixteenth semiconductor chip 198, may be upwardly exposed.

A third conductive wire 200 may electrically connect the fourth group of the semiconductor chip 190 with the logic chip 160. Because the logic chip 160 may be electrically connected with the package substrate 110 via the conductive bump 162, the third conductive wire 200 may indirectly connect the fourth group of the semiconductor chips 190 with the package substrate 110 via the logic chip 160. In exemplary embodiments in accordance with principles of inventive concepts, the third conductive wire 200 may be extended in the first horizontal direction.

In exemplary embodiments in accordance with principles of inventive concepts, the third conductive wire 200 may include a 3-1 conductive wire 202, a 3-2 conductive wire 204, a 3-3 conductive wire 206 and a 3-4 conductive wire 208. The 3-1 conductive wire 202 may be electrically connected between the sixteenth bonding pad 199 of the sixteenth semiconductor chip 198 and the fifteenth bonding pad 197 of the fifteenth semiconductor chip 196. The 3-2 conductive wire 204 may be electrically connected between the fifteenth bonding pad 197 of the fifteenth semiconductor chip 196 and the fourteenth bonding pad 195 of the fourteenth semiconductor chip 194. The 3-3 conductive wire 206 may be electrically connected between the fourteenth bonding pad 195 of the fourteenth semiconductor chip 194 and the thirteenth bonding pad 193 of the thirteenth semiconductor chip 192. The 3-4 conductive wire 208 may be electrically connected between the thirteenth bonding pad 193 of the thirteenth semiconductor chip 192 and the redistribution layer 164 of the logic chip 160.

In this manner, in exemplary embodiments in accordance with principles of inventive concepts, the third group of the semiconductor chips 200 may be electrically connected with the package substrate 110 via the third conductive wire 200, the redistribution layer 164 and the connecting wire 166. Alternatively, the 3-4 conductive wire 208 may be connected to any one of the fourteenth bonding pad 195, the fifteenth bonding pad 197 and the sixteenth bonding pad 199.

A fourth conductive wire 210 may directly connect the third group of the semiconductor chip 180 with the package substrate 110. In exemplary embodiments in accordance with principles of inventive concepts, the fourth conductive wire 210 may be extended in the third horizontal direction.

In exemplary embodiments in accordance with principles of inventive concepts, the fourth conductive wire 210 may include a 4-1 conductive wire 212, a 4-2 conductive wire 214, a 4-3 conductive wire 216 and a 4-4 conductive wire 218. The 4-1 conductive wire 212 may be electrically connected between the twelfth bonding pad 189 of the twelfth semiconductor chip 188 and the eleventh bonding pad 187 of the eleventh semiconductor chip 186. The 4-2 conductive wire 214 may be electrically connected between the eleventh bonding pad 187 of the eleventh semiconductor chip 186 and the tenth bonding pad 185 of the tenth semiconductor chip 184. The 4-3 conductive wire 216 may be electrically connected between the tenth bonding pad 185 of the tenth semiconductor chip 184 and the ninth bonding pad 183 of the ninth semiconductor chip 182. The 4-4 conductive wire 218 may be electrically connected between the ninth bonding pad 183 of the ninth semiconductor chip 182 and the bond finger 112 of the package substrate 110. Alternatively, the 4-4 conductive wire 218 may be connected to any one of the tenth bonding pad 185, the eleventh bonding pad 187 and the twelfth bonding pad 189. Additionally, an exemplary embodiment of a multi-chip package 100d in accordance with principles of inventive concepts may include any one of the logic chips in FIG. 4, FIG. 7 and FIG. 10, for example.

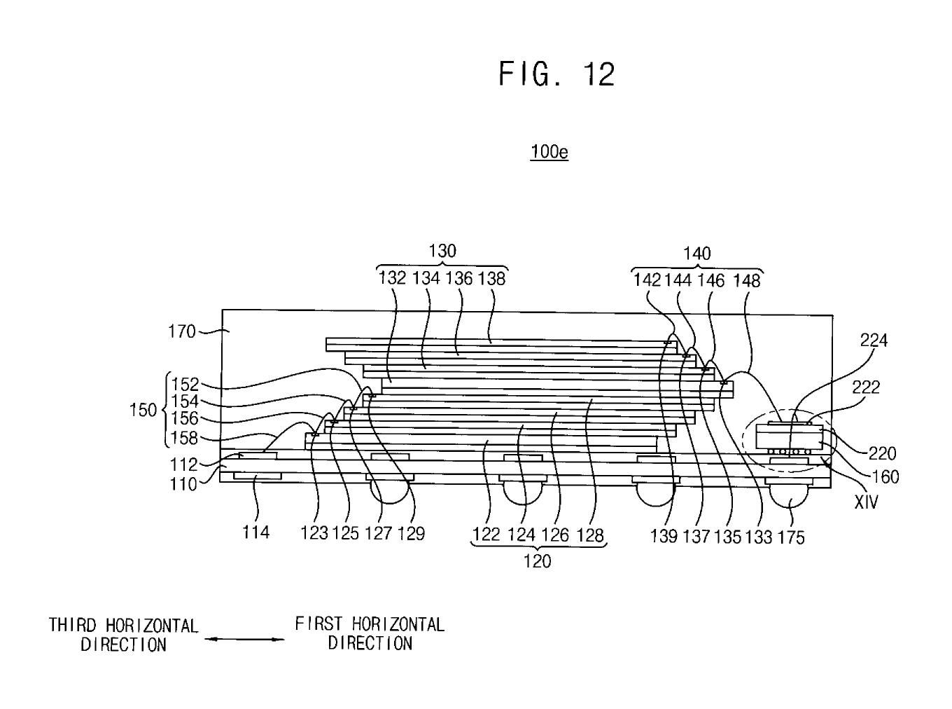

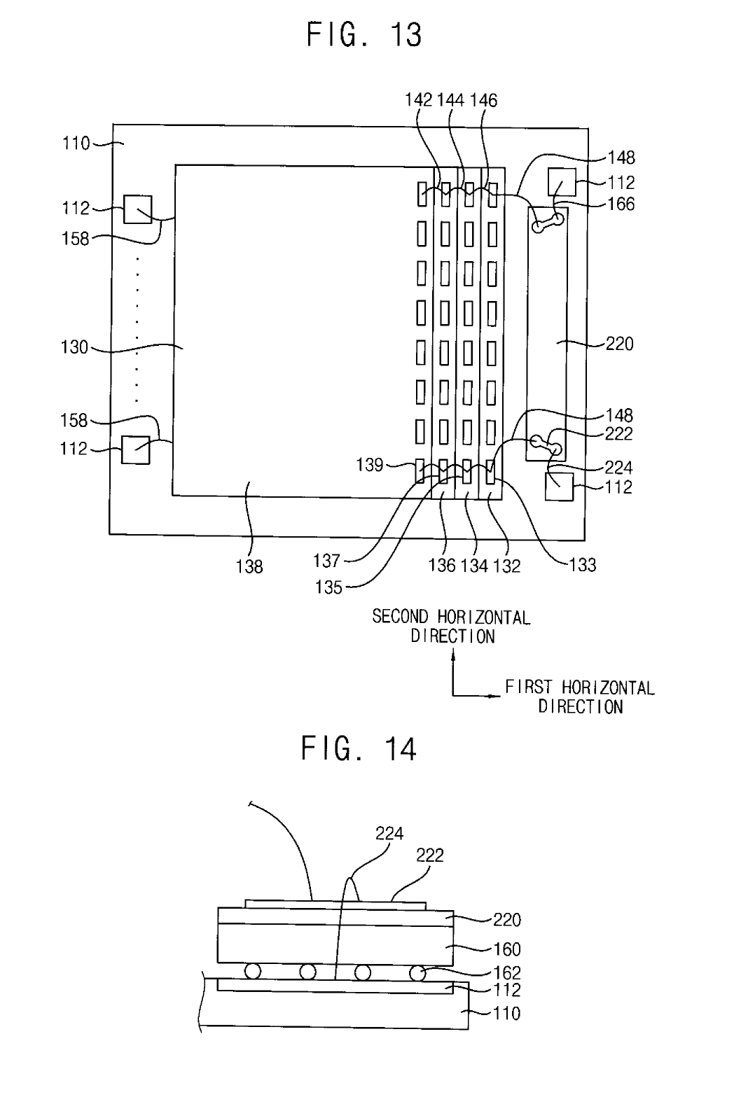

FIG. 12 is a cross-sectional view illustrating an exemplary embodiment of a multi-chip package in accordance with principles of inventive concepts, FIG. 13 is a plan view illustrating the multi-chip package substrate in FIG. 12, and FIG. 14 is an enlarged cross-sectional view of a portion “XIV” in FIG. 12.

An exemplary embodiment of a multi-chip package 100e in accordance with principles of inventive concepts may include elements substantially the same as those of the multi-chip package 100 in FIG. 1 except for further including a dummy chip. For the sake of brevity and clarity of explanation descriptions of like elements may not be repeated here.

Referring to FIGS. 12 to 14, the multi-chip package 100e of this example embodiment may further include a dummy chip 220. The dummy chip 220 may be stacked on the upper surface of the logic chip 160. By “dummy chip” we refer to a chip that does not necessarily include the logic that, for example, logic chip 160 includes and, rather than logic, dummy chip 220 may be employed for signal distribution, for example.

In exemplary embodiments in accordance with principles of inventive concepts, the dummy chip 220 may include a redistribution layer 222. The redistribution layer 222 may be arranged on an upper surface of the dummy chip 220. The 1-4 conductive wire 148 may be electrically connected between the fifth bonding pad 133 of the fifth semiconductor chip 132 and the redistribution layer 222 of the dummy chip 220. A connecting wire 224 may be electrically connected between the redistribution layer 222 of the dummy chip 220 and the bond finger 112 of the package substrate 110. The connecting wire 224 may be extended in the second horizontal direction. As a result, the connecting wire 224 may not increase the width of the multi-chip package 100e.

In exemplary embodiments in accordance with principles of inventive concepts, because the dummy chip 220 may include the redistribution layer 222 connected to the package substrate 110, the logic chip 160 may not include a redistribution layer. The logic chip 160 may be electrically connected with the fifth semiconductor chip 132 via the package substrate 110, the connecting wire 224, the redistribution layer 222 and the 1-4 conductive wire 148.

In exemplary embodiments in accordance with principles of inventive concepts a multi-chip package may include an even number of groups (for example, two or four groups) of semiconductor chips or an odd number of groups (for example, three or five) groups of semiconductor chips.

According to exemplary embodiments in accordance with principles of inventive concepts, the first conductive wire may electrically connect the semiconductor chips with the package substrate via the logic chip. In this manner, it may not be required to form a bond finger, which may be connected to the first conductive wire, on the package substrate and, as a result, the logic chip may not increase the width of the multi-chip package. Additionally, logic chip may be located far enough away from the lowermost group of semiconductor chips to allow a sufficient amount of molding member to be introduced to avoid the introduction of voids in molding member.

The foregoing is illustrative of exemplary embodiments in accordance with principles of inventive concepts and is not to be construed as limiting thereof. Although a few exemplary embodiments in accordance with principles of inventive concepts have been described, those skilled in the art will readily appreciate that many modifications are possible in the exemplary embodiments in accordance with principles of inventive concepts without materially departing from the novel teachings and advantages of inventive concepts. Accordingly, all such modifications are intended to be included within the scope of the inventive concepts as defined in the claims.

What is claimed is:

1. A multi-chip package comprising:
a package substrate;
a plurality of semiconductor chips stacked stepwise on an upper surface of the package substrate;
a logic chip including a conductive bump that is electrically connected to the package substrate; and
a first conductive wire electrically connected between the semiconductor chips and the logic chip.

2. The multi-chip package of claim 1, wherein the logic chip comprises a redistribution layer connected to the first conductive wire.

3. The multi-chip package of claim 2, wherein the logic chip further comprises a connecting wire electrically connected between the redistribution layer and the package substrate.

4. The multi-chip package of claim 3, wherein the connecting wire is extended in a second horizontal direction substantially perpendicular to a first horizontal direction that correspond to an extending direction of the first conductive wire.

5. The multi-chip package of claim 2, wherein the logic chip further comprises a plug formed in the logic chip to electrically connect the redistribution layer with the conductive bump.

6. The multi-chip package of claim 2, wherein the logic chip further comprises a connecting line formed on an outer surface of the logic chip to electrically connect the redistribution layer with the conductive bump.

7. The multi-chip package of claim 1, further comprising a second conductive wire directly connected between the semiconductor chips and the package substrate.

8. The multi-chip package of claim 1, wherein the semiconductor chips are stacked in a stepwise shape.

9. The multi-chip package of claim 8, wherein the semiconductor chips comprise:
a first group of semiconductor chips stacked on the package substrate stepwise in a first horizontal direction, the first group of the semiconductor chips directly connected to the package substrate; and
a second group of semiconductor chips stacked on the first group of the semiconductor chips stepwise in a third horizontal direction substantially opposite to the first horizontal direction, the second group of the semiconductor chips electrically connected with the logic chip via the first conductive wire.

10. The multi-chip package of claim 9, wherein the logic chip is positioned under the second group of the semiconductor chips protruded from the first group of the semiconductor chips in the first horizontal direction.

11. The multi-chip package of claim 1, further comprising:
a molding member formed on the upper surface of the package substrate to cover the semiconductor chips and the logic chip; and
external terminals mounted on a lower surface of the package substrate.

12. A multi-chip package comprising:
a package substrate;
a plurality of semiconductor chips stacked stepwise on an upper surface of the package substrate;
a logic chip including a conductive bump that is electrically connected to the package substrate;
a dummy chip stacked on the logic chip, the dummy chip electrically connected with the logic chip via the package substrate; and
a first conductive wire electrically connected between the semiconductor chips with the dummy chip.

13. The multi-chip package of claim 12, wherein the dummy chip comprises a redistribution layer connected to the first conductive wire.

14. The multi-chip package of claim 13, wherein the dummy chip further comprises a connecting wire electrically connected between the redistribution layer and the package substrate.

15. The multi-chip package of claim 14, wherein the connecting wire is extended in a second horizontal direction substantially perpendicular to a first horizontal direction that correspond to an extending direction of the first conductive wire.

16. An electronic device, comprising:
a package substrate;
a plurality of semiconductor chips stacked stepwise on an upper surface of the package substrate, thereby exposing bonding pads on edge portions of the chips;
a logic chip including a conductive bump that is electrically connected to the package substrate; and
a first conductive wire electrically connected between the semiconductor chips and the logic chip.

17. The electronic device of claim 16, wherein a first group of semiconductor chips is stacked stepwise in a first direction and a second group of semiconductor groups is stacked stepwise on top of the first group of semiconductor group in the opposite stepwise direction from that of the first group.

18. The electronic device of claim 17, wherein there is an even number of groups of semiconductor chips stacked in opposite stepwise directions on top of one another.

19. The electronic device of claim 17, wherein there are an odd number of groups of semiconductor chips stacked in opposite stepwise directions on top of one another.

20. The electronic device of claim 17, further comprising:
a dummy chip including a redistribution layer stacked on the logic chip, the dummy chip electrically connected with the logic chip via the package substrate, wherein the conductive wire is electrically connected between the semiconductor chip and the dummy chip.
